(19) United States
(12) Patent Application Publication
(10) Pub. No.: US 2020/0365783 A1
(43) Pub. Date: Nov. 19, 2020

(54) PACKAGING STRUCTURE OF LIGHT EMITTING DIODE

(71) Applicant: ADVANCED OPTOELECTRONIC TECHNOLOGY, INC., Hsinchu Hsien (TW)

(72) Inventors: HOU-TE LIN, Hsinchu (TW); PIN-CHUAN CHEN, Hsinchu (TW); WEN-LIANG TSENG, Hsinchu (TW); LUNG-HSIN CHEN, Hsinchu (TW); HSIN-CHIANG LIN, Hsinchu (TW); CHAO-HSIUNG CHANG, Hsinchu (TW)

(21) Appl. No.: 16/458,493

(22) Filed: Jul. 1, 2019

(30) Foreign Application Priority Data
May 13, 2019 (CN) 201910394499.1

(51) Int. Cl. H01L 33/62

(52) U.S. Cl. CPC H01L 33/62; H01L 33/50

(57) ABSTRACT

A packaging structure of an LED comprises a substrate with first surface, a first electrode arranged on the first surface, at least one light emitting chip on the first electrode, and a packaging body arranged on the first surface to cover the light emitting chip. The first surface defines at least one groove, part of the package body is in the groove. By increasing the contact area between the substrate and the packaging body or mounting an embedded structure on the substrate, the firmness of the bond between the packaging body and the substrate is improved.

### FIELD

The subject matter herein generally relates to light emitting diodes (LEDs) packaging structure.

### BACKGROUND

An LED packaging structure comprises a substrate and an encapsulation layer mounted on the substrate. Usually, the encapsulation layer is directly attached to the substrate, or bonded to the substrate by glue.

With the gradual reduction and thinning of the size of LED packaging structure, the contact area between the substrate and the encapsulation layer decreases, thus the bonding may not be not strong enough to keep the substrate and the encapsulation layer firmly connected together.

### BRIEF DESCRIPTION OF THE DRAWINGS

Implementations of the present technology will now be described, by way of embodiment, with reference to the attached figures.

FIG. 1A is top diagrammatic view of a first embodiment of an LED packaging structure.

FIG. 1B is a side diagrammatic view of the LED packaging structure of FIG. 1A.

FIG. 1C is a bottom diagrammatic view of the LED packaging structure of FIG. 1A.

FIG. 2A is top diagrammatic view of a second embodiment of an LED packaging structure.

FIG. 2B is a side diagrammatic view of the LED packaging structure of FIG. 2A.

FIG. 2C is a bottom diagrammatic view of the LED packaging structure of FIG. 2A.

FIG. 3A is top diagrammatic view of a third embodiment of an LED packaging structure.

FIG. 3B is a side diagrammatic view of the LED packaging structure of FIG. 3A.

FIG. 3C is a bottom diagrammatic view of the LED packaging structure of FIG. 3A.

FIG. 4A is top diagrammatic view of a fourth embodiment of an LED packaging structure.

FIG. 4B is a side diagrammatic view of the LED packaging structure of FIG. 4A.

FIG. 4C is a bottom diagrammatic view of the LED packaging structure of FIG. 4A.

FIG. 4D is similar to FIG. 4A, but showing the LED packaging structure from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

### First Embodiment

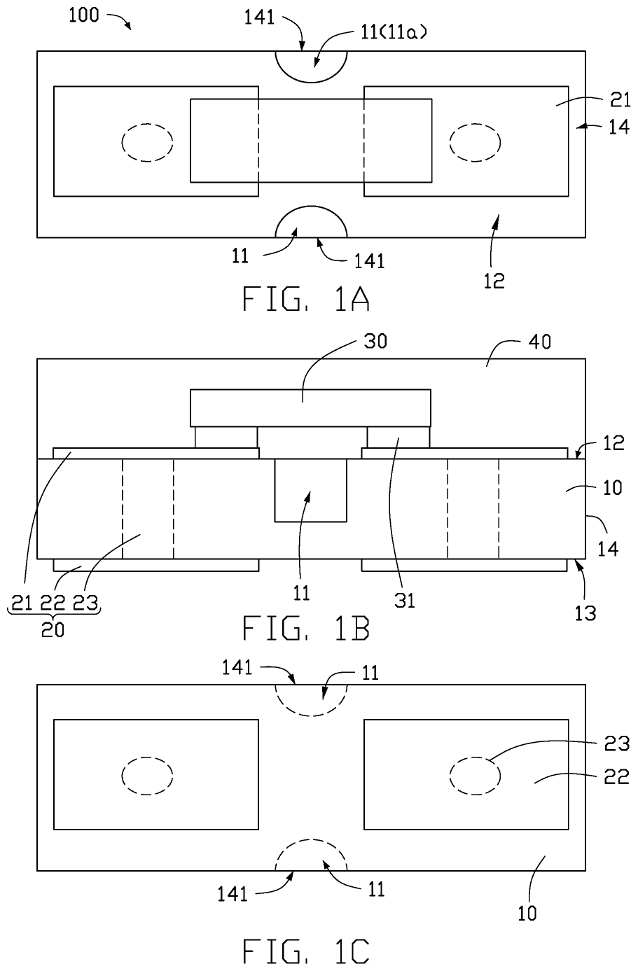

FIGS. 1A-1C illustrate an LED packaging structure 100 comprising a substrate 10. The substrate 10 comprises a first surface 12. The LED packaging structure 100 further comprises a first electrode 12 arranged on the first surface 12, at least one light emitting chip 30 arranged on and electrically coupled to the first electrode 12, and a package body 40 arranged on the first surface 12. The package body 40 covers the light emitting chip 30. The first surface 12, being concave, defines at least one groove 11. A part of the package body 40 is received in the groove 11 to increase the contact area between the package body 40 and the substrate 10, so that the package body 40 and the substrate 10 are firmly connected. The light emitting chip 30 can be a light emitting diode.

The substrate 10 further comprises a second surface 13 opposite to the first surface 12 and a plurality of side surfaces 14 connecting the first surface 12 and the second surface 13. An area of the first surface 12 near the side surface 14 sinks toward the second surface 13 to form the at least one groove 11. The grooves 11 can be distributed symmetrically around the light emitting chip 30. For example, areas of the first surface 12 adjacent to the side surface 14 inwardly sink to form two grooves 11. The central axis of the groove 11 is perpendicular to an extending direction of the substrate 10. The groove 11 does not penetrate the substrate 10. The groove 11 along the central axis is consistent in cross section. That is, the groove 11 is geometrically straight.

In an alternative embodiment, the cross-section area of the groove 11 is substantially semicircular, and the groove 11 comprises an opening 14 formed on the side surface 14.

The electrode 20 further comprises a second electrode 22 and a connecting portion 23 connecting the first electrode 21 and the second electrode 22. The second electrode 22 is arranged on the second surface 13, and the location of the second electrode 22 corresponds to that of the first electrode 21. The connecting portion 23 is formed across the first surface 12 and the second surface 13, and electrically connects the first electrode 21 and the second electrode 22. The second electrode 22 is electrically connected to an external power source (not shown), which provides electrical energy.

In an alternative embodiment, the light emitting chip 30 is electrically connected to the first electrode 21 by flip chip technology. The light emitting chip 30 and the first electrode 21 are electrically connected by a solder ball 31.

In an alternative embodiment, the package body 40 define an element capable of converting wavelengths of light, which converts the light emitted by the light emitting chip into white light. In an alternative embodiment, the package body 40 is made of the wavelength converting material.

### Second Embodiment

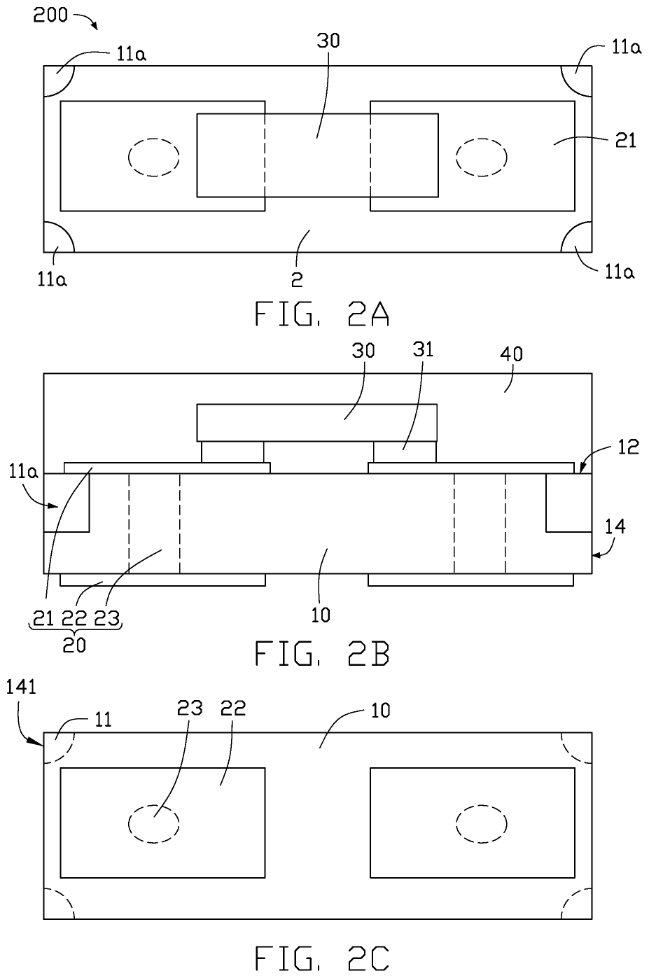

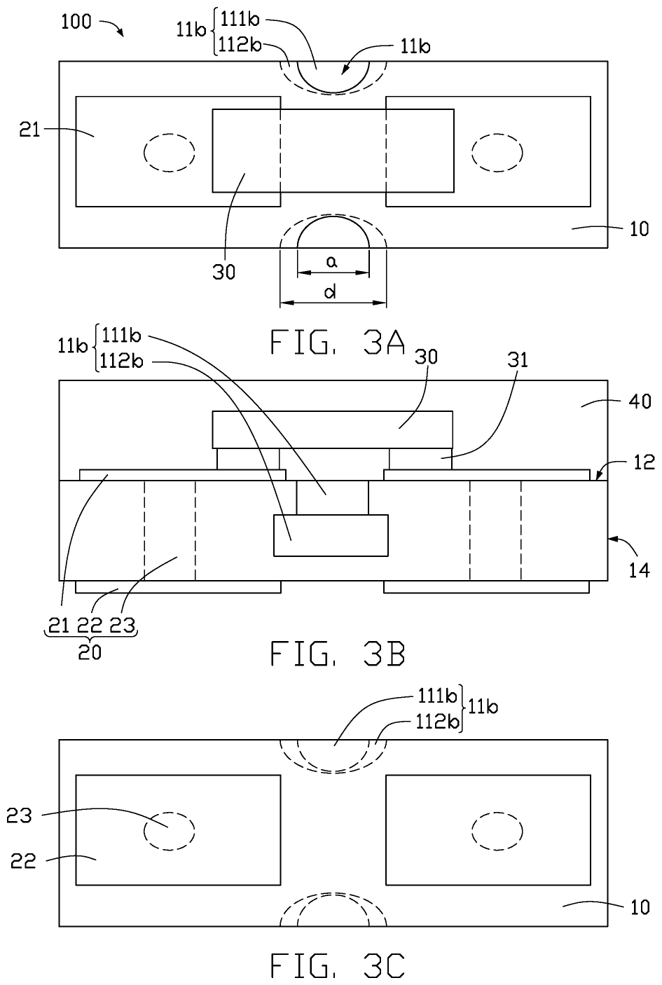

FIGS. 2A-2C illustrate an LED packaging structure 200. The difference between the second embodiment and the first embodiment is that the grooves 11 in the second embodiment are at the corners of the substrate 10. For example, the first surface 12 inwardly sinks at four corners of the substrate 10 to form four grooves 11, and the cross-section area of each groove 11 is a quarter circle.

### Third Embodiment

FIGS. 3A-3C illustrate an LED packaging structure 300. The difference between the third embodiment and the first embodiment is that the groove 11 in the third embodiment is substantially a stepped hole. The groove 11 comprises a first portion 111b and a second portion 112b communicating with the first portion 111b. The first portion 111b is close to the first surface 12, and the aperture of the first portion 111b is a. The second portion 112b is far away from the first surface 12, and the aperture of the second portion 112 is b, where b>a. A part of the package body 40 enters into the second portion 112b from the first portion 111b, thus part of the package body 40 is embedded into the interior of the substrate 10, and the fastness of the connection of the package body 40 in combination with the substrate 10 is improved.

### Fourth Embodiment

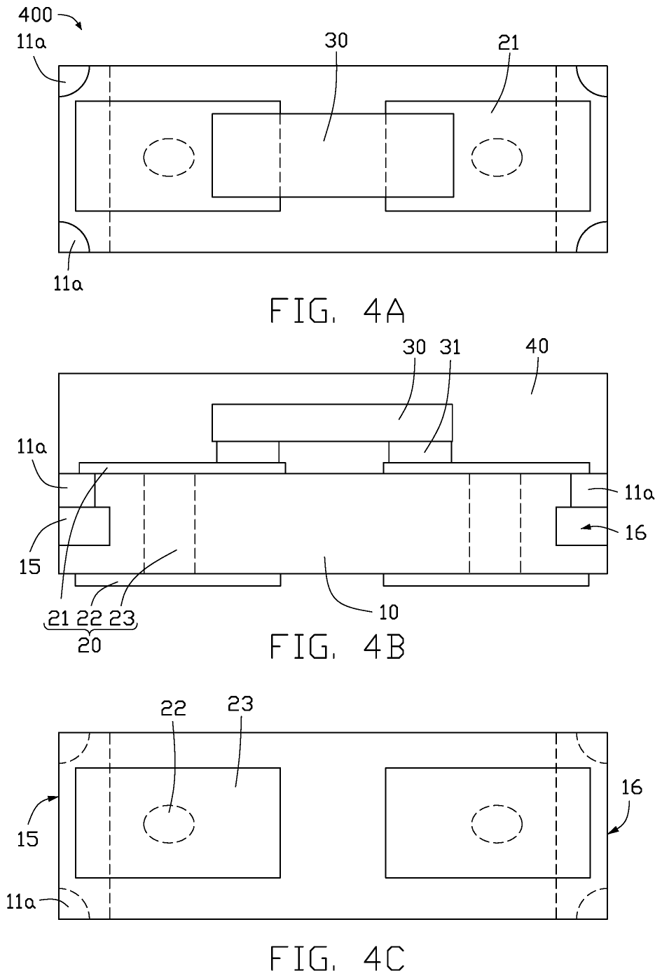

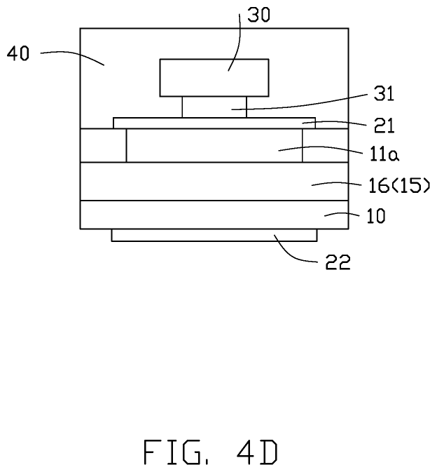

FIGS. 4A-4D illustrate an LED packaging structure 400. The difference between the fourth embodiment and the second embodiment is that bottoms of adjacent two of the at least two grooves 11 in the fourth embodiment communicate with each other to form a communicating portion 15, which is formed across the side surface 14 of the substrate 10. A part of the package body 40 enters into the groove 11, and is received in the communicating portion 15 to connect the two adjacent grooves 11. Since a part of the package body 40 is embedded in the interior of the substrate 10, the fastness of connection of the package body 40 in combination with the substrate is improved. By increasing the contact area between the substrate and the packaging body, the firmness of the bond between the packaging body and the substrate is improved.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A packaging structure of a light emitting diode (LED) comprising:
a substrate defining a first surface;
a first electrode arranged on the first surface;
at least one light emitting chip arranged on and electrically coupled to the first electrode; and
a package body arranged on the first surface, and covering the light emitting chip,
wherein the first surface defines at least one groove, the at least one groove is configured to receive a part of the package body.

2. The packaging structure of the LED of claim 1, wherein the substrate further defines a second surface opposite to the first surface and a plurality of side surfaces connecting the first surface and the second surface, an area of the first surface near the side surfaces sinks toward the second surface to form the at least one groove.

3. The packaging structure of the LED of claim 2, wherein the cross-section area of the groove is semicircular, and the groove comprises an opening formed on the side surface.

4. The packaging structure of the LED of claim 2, wherein the groove is a stepped hole, and comprise a first portion and a second portion, the first portion is nearer to the first surface than the second portion, the second portion communicates with the first portion, a size of the first portion is smaller than a size of the second portion.

5. The packaging structure of the LED of claim 1, wherein the substrate further comprises a second surface opposite to the first surface and a plurality of side surfaces connecting the first surface and the second surface, the first surface inwardly sinks at the corners of the substrate to form the groove.

6. The packaging structure of the LED of claim 5, wherein bottoms of adjacent two of the at least two grooves communicate with each other to form a communicating portion, the communicating portion are formed across the side surface of the substrate, and a part of the package body is received in the at least two grooves and the communicating portion to connect the two adjacent grooves.

7. The packaging structure of the LED of claim 1, wherein a central axis of the groove is perpendicular to an extending direction of the substrate.

8. The packaging structure of the LED of claim 1, wherein the LED packaging structure further comprise a second electrode arranged on the second surface and opposite to the first electrode, and a connecting portion connecting the first electrode and the second electrode, the connecting portion being formed across the first surface and the second surface.

9. The packaging structure of the LED of claim 8, wherein the light emitting chip is electrically coupled to the first electrode by flip chip technology.

10. The packaging structure of the LED of claim 1, wherein the groove does not penetrate the substrate.

11. The packaging structure of the LED of claim 10, wherein the groove is a straight hole.

12. The packaging structure of the LED of claim 1, wherein the package body defines an element capable of converting wavelength light.
